(19) United States
(12) Patent Application Publication
(10) Pub. No.: US 2021/0379771 A1
(43) Pub. Date: Dec. 9, 2021

(54) VACUUM SUCTION PEN AND METHOD FOR USING THE SAME

(71) Applicant: TRIPLE WIN TECHNOLOGY(SHENZHEN) CO.LTD., Shenzhen (CN)

(72) Inventors: YAO-WEI HONG, Shenzhen (CN); AI-NING WANG, Shenzhen (CN); LONG-FEI LIU, Shenzhen (CN); GAO-YANG DENG, Shenzhen (CN); YEN-SHENG LIN, New Taipei (TW)

(21) Appl. No.: 16/916,064

(22) Filed: Jun. 29, 2020

(30) Foreign Application Priority Data
Jun. 9, 2020 (CN) 202010526449.7

(51) Int. Cl. B25J 15/06; B25J 1/04

(52) U.S. Cl. CPC B25J 15/065; B25J 1/04

(57) ABSTRACT

A vacuum suction pen which can always be held squarely above a work being done notwithstanding the orientation of a component to be fitted to the work includes a penholder, a pen head, a connecting mechanism, and a suction cup. The suction cup is at an end of the pen head away from the penholder and made of rubber for soft handling. The connecting mechanism is coupled to the penholder and the pen head, and comprises a connecting member, the connecting member comprises a first connecting portion and a second connecting portion, the first connecting portion is disposed in the penholder, the second connecting portion is coupled to the pen head, and the pen head can be rotationally disposed on the penholder. A method for using the vacuum suction pen is also provided.

### FIELD

The subject matter herein generally relates to a vacuum suction pen and a method for using the vacuum suction pen.

### BACKGROUND

A vacuum suction pen looks like a pen, is a small pneumatic tool for handling components, can be used in the assembly of small parts, and is non-marking and not damaging to parts. Due to different orientations of the components to be lifted (sucked), a traditional vacuum suction pen has difficulties dealing with a large number of scattered components. An operator may need to jiggle or move the component to change its orientation and then suck it, or twist the wrist after sucking, and then move it to a required position. On the one hand, trying to be efficient may damage the component, on the other hand, trying to be careful may cause muscle spasms in the operator's hand, and there is a problem of poor adjustability, which affects the operation efficiency.

Therefore, improvement is desired.

### BRIEF DESCRIPTION OF THE DRAWINGS

Implementations of the present disclosure will now be described, by way of embodiments, with reference to the attached figures.

FIG. 1 is a schematic diagram of an embodiment of a vacuum suction pen of the present disclosure.

FIG. 2 is an exploded diagram of an embodiment of the vacuum suction pen of FIG. 1.

FIG. 3 is a schematic diagram of an embodiment of a connecting member of the vacuum suction pen of FIG. 1.

FIG. 4 is a schematic diagram of an embodiment of a suction cup of the vacuum suction pen of FIG. 1.

FIG. 5 is a flowchart of an embodiment of a method for using the vacuum suction pen of the present disclosure.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series, and the like.

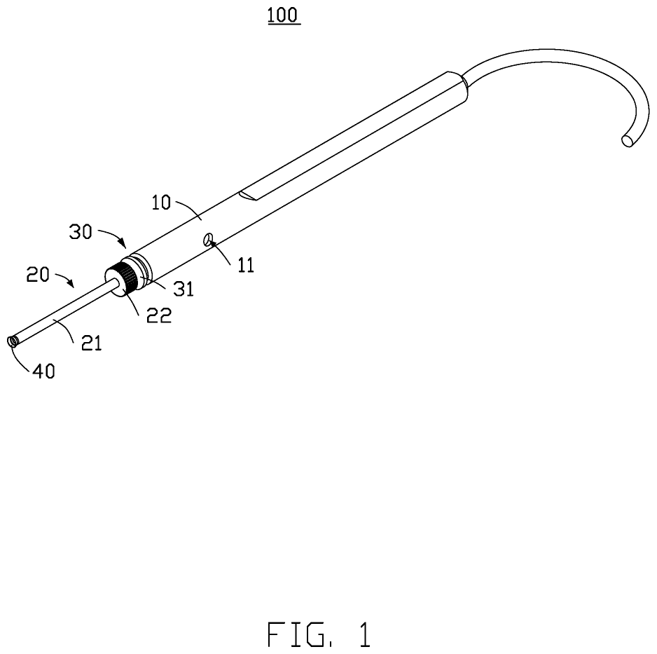

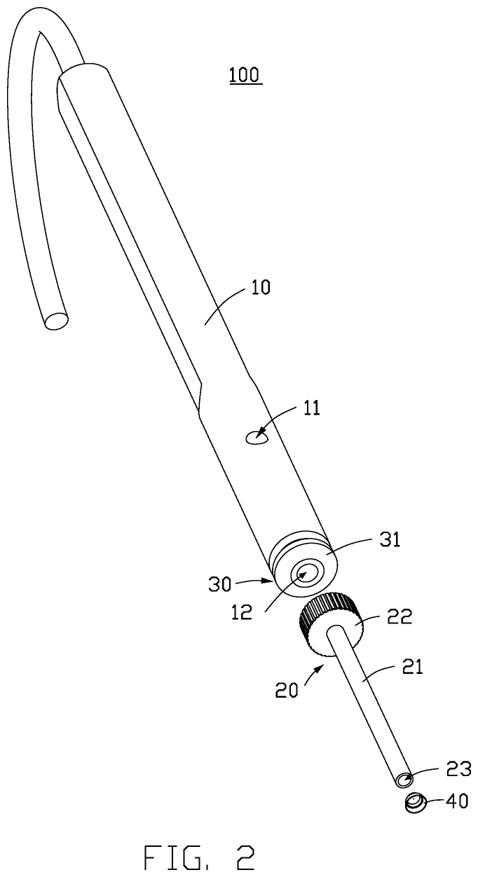

FIGS. 1 and 2 illustrate a vacuum suction pen 100 in accordance with an embodiment of the present disclosure.

In the embodiment, the vacuum suction pen 100 is used to pick up (suck) and place components (not shown).

In the embodiment, the vacuum suction pen 100 includes a penholder 10, a pen head 20, a connecting mechanism 30, and a suction cup 40.

In the embodiment, the connecting mechanism 30 is connected to the penholder 10 and the pen head 20.

In the embodiment, the suction cup 40 is disposed at an end of the pen head 20 away from the penholder 10 for sucking the components.

In one embodiment, the penholder 10 has a hollow structure. The penholder 10 may be a structure with a uniform diameter or a hollow tubular structure with a variable diameter.

In one embodiment, inside of the penholder 10 defines a vacuum chamber 12, and the vacuum chamber 12 forms a vacuum area.

In one embodiment, the penholder 10 defines a vacuum opening 11, the vacuum opening 11 communicates with the vacuum chamber 12, and the vacuum opening 11 is used to control the vacuum chamber 12, so as to cancel the suction and lower the components into place.

In one embodiment, the penholder 10 is a hollow tubular structure with a varying diameter.

In one embodiment, a first end of the penholder 10 shrinks in an axial direction, and a diameter of a second end of the penholder 10 shrinks away from the vacuum opening 11. The cross section of the penholder 10 is substantially elliptical, and there is matte surface finish of the penholder 10, for grip and to prevent slipping during use.

The pen head 20 includes a pen body 21 and a turntable 22, and the turntable 22 is disposed at one end of the pen body 21.

In one embodiment, the pen body 21 is a hollow tubular structure, and the pen body 21 defines an air channel 23. The air channel 23 is connected to the vacuum chamber 12.

In one embodiment, the surface of the pen body 21 is a smooth surface to reduce dust contamination and prevent contamination of the components during use. The surface of the penholder 10 can be frosted.

In one embodiment, the turntable 22 is integrally connected to the pen body 21, and the turntable 22, of a diameter similar to that of the pen body 21, forms a cap to the pen body 21 in the manner of a disc.

In one embodiment, the turntable 22 is threadedly connected to the pen body 21, and the turntable 22 is provided with threads, which increases friction and allows rotation by an operator in use.

In one embodiment, the connecting mechanism 30 includes a connecting member 31, and the connecting member 31 is disposed at one end of the turntable 22.

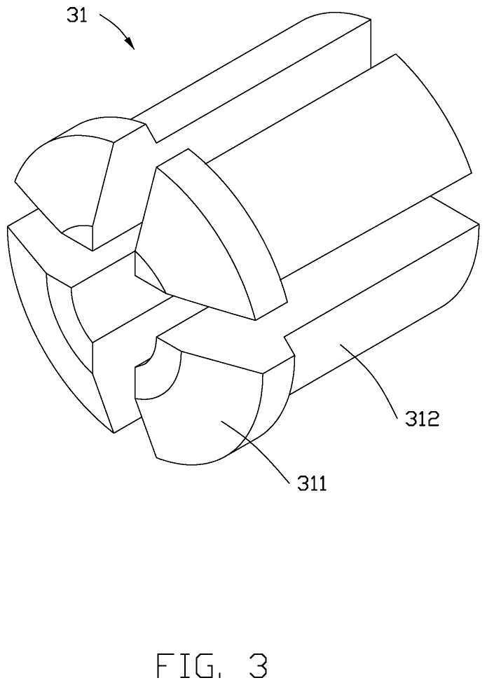

FIG. 3 illustrates that the connecting member 31 includes a first connecting portion 311 and a second connecting portion 312. In one embodiment, the first connecting portion 311 is disposed in the penholder 10. The second connecting portion 312 is connected to the pen body 21, and the pen head 20 is rotationally disposed on the penholder 10.

In one embodiment, the connecting member 31 is generally pointed and segmented, being divided into four parts in this embodiment. The first connecting portion 311 is contracted by an external force and inserted into the penholder 10. When the first connecting portion 311 is not stressed, the first connecting portion 311 is tightly locked in the penholder 10 to achieve an airtight connection between the connecting mechanism 30 and the penholder 10.

The connecting member 31 with the pen head 20 can be rotated around the axis of the penholder 10.

In one embodiment, a size of an inner diameter of the connecting member 31 is the same as a size of an outer diameter of the pen body 21.

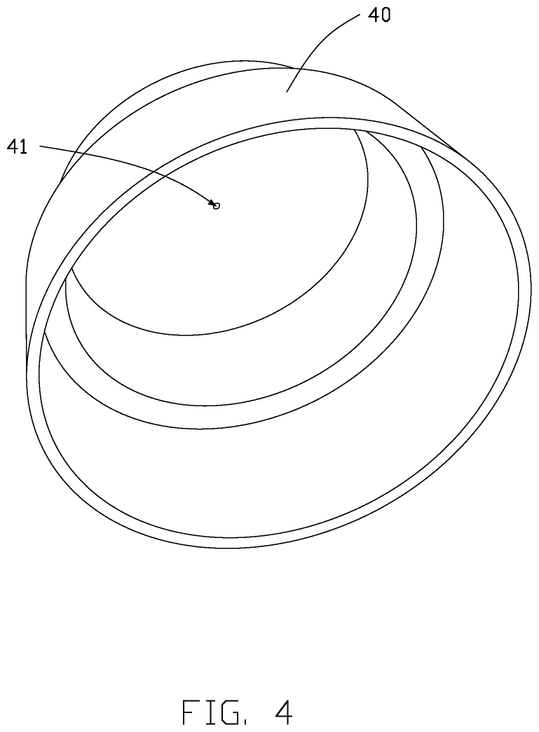

FIG. 4 illustrates the suction cup 40 which is a rubber suction cup defining an air hole 41.

In one embodiment, the suction cup 40 is generally trumpet-shaped. The air hole 41 of the suction cup 40 is connected to the vacuum chamber 12 of the penholder 10 and the air channel 23 of the pen body 21.

When the suction cup 40 is in use, the suction cup 40 can be configured to match one or more components to be sucked.

The suction cup 40 of soft rubber protects the surface of the component. In one embodiment, the pen head 20 is covered with a rubber suction cup to protect a sucked component.

When the vacuum suction pen 100 is installed, the first connecting portion 311 is tightly inserted into the penholder 10, so that the air channel 23 of the pen body 21 is in airtight communication with the vacuum chamber 12 of the penholder 10.

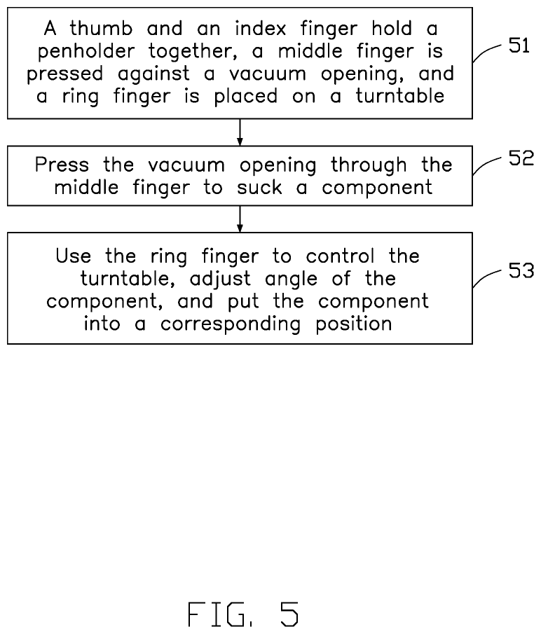

FIG. 5 illustrates a flowchart of a method for using the vacuum suction pen 100. The method for using the vacuum suction pen 100 may include the following steps.

In block 51, a thumb and an index finger hold the penholder 10, a middle finger presses against the vacuum opening 11, and a ring finger is placed on the turntable 22.

In block 52, the vacuum opening 11 is pressed with the middle finger to activate a vacuum.

In block 53, the ring finger controls the turntable 22, adjusts an angle of a component, and puts the component into a required position.

The vacuum suction pen 100 can always be held squarely above the work in the manner of a straight-tip brush. The ring finger of the operator controls the turntable 22, adjusts the angle of the component, puts it into a position, reduces multiple sucks and holds of a component, reduces the amount of hand movement of the operator, and so eliminates fatigue caused by wrist-twisting and straining. Handling efficiency is improved.

Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will, therefore, be appreciated that the exemplary embodiments described above may be modified within the scope of the claims.

What is claimed is:

1. A vacuum suction pen comprising:
a penholder;
a pen head;
a suction cup disposed at an end of the pen head away from the penholder; and
a connecting mechanism coupled to the penholder and the pen head, and comprising a connecting member;
wherein the connecting member comprises a first connecting portion and a second connecting portion, the first connecting portion is disposed in the penholder, the second connecting portion is coupled to the pen head, and the pen head is rotationally disposed on the penholder.

2. The vacuum suction pen according to claim 1, wherein the penholder defines a vacuum chamber and a vacuum opening, and the vacuum opening communicates with the vacuum chamber.

3. The vacuum suction pen according to claim 2, wherein the penholder is a hollow tubular structure with a varying diameter, and a diameter of an end of the penholder shrinks away from the vacuum opening.

4. The vacuum suction pen according to claim 2, wherein the pen head comprises a pen body and a turntable, and the turntable is disposed at an end of the pen body.

5. The vacuum suction pen according to claim 4, wherein the pen body is a hollow tubular structure, the pen body defines an air channel, and the air channel is coupled to the vacuum chamber.

6. The vacuum suction pen according to claim 5, wherein the turntable is connected to the pen body, and the turntable is provided with threads in a circumferential direction.

7. The vacuum suction pen according to claim 5, wherein a size of an inner diameter of the connecting member is the same as a size of an outer diameter of the pen body.

8. The vacuum suction pen according to claim 5, wherein the suction cup defines an air hole, and the air hole of the suction cup is connected to the vacuum chamber of the penholder and the air channel of the pen body.

9. The vacuum suction pen according to claim 5, wherein a surface of the pen head is a smooth surface, and a surface of the penholder is frosted.

10. The vacuum suction pen according to claim 1, wherein the suction cup is a rubber suction cup.

11. A vacuum suction pen comprising:
a penholder;
a pen head;
a suction cup disposed at an end of the pen head away from the penholder; and
a connecting mechanism coupled to the penholder and the pen head, and comprising a connecting member;
wherein the connecting member comprises a first connecting portion and a second connecting portion, the first connecting portion is disposed in the penholder, the second connecting portion is coupled to the pen head, and the pen head is rotationally disposed on the penholder.
wherein the penholder defines a vacuum chamber and a vacuum opening, and the vacuum opening communicates with the vacuum chamber; and
wherein the penholder is a hollow tubular structure with a varying diameter, and a diameter of an end of the penholder shrinks away from the vacuum opening.

12. The vacuum suction pen according to claim 11, wherein the pen head comprises a pen body and a turntable, and the turntable is disposed at an end of the pen body.

13. The vacuum suction pen according to claim 12, wherein the pen body is a hollow tubular structure, the pen body defines an air channel, and the air channel is coupled to the vacuum chamber.

14. The vacuum suction pen according to claim 13, wherein the turntable is connected to the pen body, and the turntable is provided with threads in a circumferential direction.

15. The vacuum suction pen according to claim 13, wherein a size of an inner diameter of the connecting member is the same as a size of an outer diameter of the pen body.

16. The vacuum suction pen according to claim 13, wherein the suction cup defines an air hole, and the air hole of the suction cup is connected to the vacuum chamber of the penholder and the air channel of the pen body.

17. The vacuum suction pen according to claim 13, wherein a surface of the pen head is a smooth surface, and a surface of the penholder is frosted.

18. The vacuum suction pen according to claim 11, wherein the suction cup is a rubber suction cup.

19. A method for using a vacuum suction pen comprising:
holding a penholder by a thumb and an index finger;
placing a ring finger on a turntable;
pressing a vacuum opening with a middle finger to suck a component; and
controlling the turntable through the ring finger, adjusting an angle of the component, and putting the component into a required position.
